(19) United States
(12) Patent Application Publication
(10) Pub. No.: US 2025/0191886 A1
(43) Pub. Date: Jun. 12, 2025

(54) SHOWERHEAD ASSEMBLY AND SUBSTRATE PROCESSING APPARATUS COMPRISING THE SAME

(71) Applicant: SEMES CO., LTD., Cheonan-si (KR)

(72) Inventors: Sun Il KIM, Chungcheongnam-do (KR); Jin Il SUNG, Gyeonggi-do (KR); Sun June KIM, Seoul (KR)

(73) Assignee: SEMES CO., LTD., Cheonan-si (KR)

(21) Appl. No.: 18/916,864

(22) Filed: Oct. 16, 2024

(30) Foreign Application Priority Data
Dec. 8, 2023 (KR) 10-2023-0177249

(51) Int. Cl. H01J 37/32

(52) U.S. Cl. CPC H01J 37/3244; H01J 37/32899; H01J 2237/334

(57) ABSTRACT

A showerhead assembly of a substrate processing apparatus, which is positioned below a gas distribution plate in which a first coupling groove is formed, comprises a showerhead plate provided with an insertion groove formed at a position facing the first coupling groove in a vertical direction; a bush unit inserted into the insertion groove and formed with a second coupling groove having the same central axis as that of the first coupling groove; and a fastening unit coupled to the first coupling groove and the second coupling groove, wherein the insertion groove has an area of a lower end, which is larger than that of an upper end, and the bush unit has one side and the other side, which are asymmetrical based on the second coupling groove, and is separated into two or more.

### CROSS-REFERENCE TO RELATED APPLICATION

This application claims priority from Korean Patent Application No. 10-2023-0177249 filed on Dec. 8, 2023 in the Korean Intellectual Property Office and all the benefits accruing therefrom under 35 U.S.C. 119, the contents of which in its entirety are herein incorporated by reference.

### BACKGROUND

### Technical Field

The present disclosure relates to a showerhead assembly and a substrate processing apparatus comprising the same.

### Description of the Related Art

Plasma refers to an ionized gas state composed of ions, electrons, radicals, etc., and may be generated by high temperature or RF electromagnetic fields. A semiconductor device fabricating process may include an etching process using plasma or an ashing process. A process of processing a substrate such as a wafer by using plasma is performed by colliding ions and radical particles, which are contained in the plasma, with the wafer.

A showerhead may be provided in an apparatus for processing a substrate by using plasma. The showerhead may be disposed below a gas distribution plate. The gas distribution plate may be made of a metal material, and may be grounded. The showerhead may be made of a material containing silicon (Si).

The gas distribution plate and the showerhead may be coupled to each other by a bolt. When the bolt is directly screwed to the showerhead, since the showerhead may be damaged, a bush may be provided in the showerhead to prevent the showerhead from being damaged. The bush is screwed to the bolt, and the showerhead and the gas distribution plate may be fastened via the bush and the bolt.

For close coupling between the showerhead and the distribution plate of different materials, the bush is screwed into a groove (cylindrical structure) formed on an upper surface of the showerhead. That is, a thread is formed on an inner circumferential surface of the groove of the showerhead so that the bush may be screwed to the thread, whereby the bush does not fall out again after being inserted into the showerhead. In addition, the bolt is screwed to the bush inserted into the showerhead so that the showerhead and the distribution plate may be coupled to each other.

However, the showerhead is reused through a cleaning and/or re-polishing process after a substrate processing process, and a process of coupling the bush to the showerhead after removing the bush from the showerhead is repeated for the cleaning and/or re-polishing process. In this repeated process, as a thread is formed in the groove of the showerhead to which the bush is coupled, cracks may be easily generated by the thread. That is, the thread may cause cracks. For example, when the bush is screwed to the showerhead, a force is transferred to the thread to cause cracks, or when the bush is removed after the substrate processing process, cracks may occur due to a screwing force.

When cracks occur in the showerhead, it is difficult to perform the cleaning or re-polishing process, and the showerhead is damaged by crack propagation, and thus the showerhead is often discarded, whereby improvement is required.

### BRIEF SUMMARY

An object of the present disclosure is to provide a showerhead assembly and a substrate processing apparatus comprising the same, in which a thread may be omitted in a groove (insertion groove) of a showerhead because a bush is not coupled to a showerhead by screw coupling.

The objects of the present disclosure are not limited to those mentioned above and additional objects of the present disclosure, which are not mentioned herein, will be clearly understood by those skilled in the art from the following description of the present disclosure.

A showerhead assembly of a substrate processing apparatus, which is positioned below a gas distribution plate in which a first coupling groove is formed, according to one aspect of the present disclosure devised to achieve the above objects comprises a showerhead plate provided with an insertion groove formed at a position facing the first coupling groove in a vertical direction; a bush unit inserted into the insertion groove and formed with a second coupling groove having the same central axis as that of the first coupling groove; and a fastening unit coupled to the first coupling groove and the second coupling groove, wherein the insertion groove has an area of a lower end, which is larger than that of an upper end, and the bush unit has one side and the other side, which are asymmetrical based on the second coupling groove, and is separated into two or more.

A showerhead assembly of a substrate processing apparatus, which is positioned below a gas distribution plate in which a first coupling groove is formed, according to another aspect of the present disclosure devised to achieve the above objects comprises a showerhead plate formed with an insertion groove at a position facing the first coupling groove in a vertical direction; a bush unit inserted into the insertion groove and formed with a second coupling groove having the same central axis as that of the first coupling groove; and a fastening unit coupled to the first coupling groove and the second coupling groove, wherein the insertion groove has a larger area on a lower end than on an upper end, and includes a first area having one side, a second area including the other side and a third area between the first area and the second area, the bush unit includes a first piece and a second piece, which are separated from each other in a circumferential direction and is not provided in the third area, the first piece is positioned in the first area, the second piece is positioned in the second area, and the first piece and the second piece are asymmetrical.

A substrate processing apparatus according to one aspect of the present disclosure devised to achieve the above objects comprises a chamber in which a substrate processing space for which a plasma etching process is performed is formed; a substrate support unit supporting a substrate in the substrate processing space; a gas supply unit supplying a process gas; and a showerhead assembly provided above the substrate processing space, wherein the showerhead assembly includes a gas distribution plate formed with a first coupling groove, distributing the process gas supplied from the gas supply unit to the substrate processing space; a showerhead plate positioned below the gas distribution plate, formed with an insertion groove at a position facing the first coupling groove in a vertical direction and made of a silicon material; a bush unit inserted into the insertion groove, formed with a second coupling groove having the same central axis as that of the first coupling groove and insertion groove and made of a Cerazole material; and a fastening unit coupled to the first coupling groove and the second coupling groove, the fastening unit includes an inner coupled to the second coupling groove, formed with a third coupling groove having the same central axis as that of the second coupling groove and made of a metal or plastic material, and a bolt coupled to the third coupling groove and the first coupling groove, the bush unit includes a first outer disposed at a lower portion inside the insertion groove, has one side that is in contact with the insertion groove and the other side formed with a first gap with the insertion groove when the second coupling groove constitutes the same central axis as that of the insertion groove, and a second outer disposed above the first outer inside the insertion groove and provided with a wing extended to be inserted into the first gap, the insertion groove has a larger area on a lower end than on an upper end, includes a first surface, a second surface facing the first surface, a third surface connected to each of the first surface and the second surface, and a fourth surface connected to each of the first surface and the second surface, the bush unit includes a fifth surface corresponding to the first surface, a sixth surface corresponding to the second surface, a seventh surface corresponding to the third surface and an eighth surface corresponding to the fourth surface, each of the first surface, the second surface, the fifth surface and the sixth surface has a trapezoidal shape, the fifth surface and the sixth surface of the first outer are formed to be asymmetrical, and a width between the fifth surface and the sixth surface is the same from an upper end to a lower end, a first curved surface not a corner is formed between the seventh surface of the first outer and a bottom surface of the first outer and between the eighth surface of the first outer and the bottom surface of the first outer, a maximum width of each of the fifth surface of the first outer and the sixth surface of the first outer is greater than a width of the upper end of the insertion groove, a width of the bottom surface of the first outer is smaller than the width of the upper end of the insertion groove, and a second curved surface not a corner is formed between the eighth surface of the second outer and a bottom surface of the second outer, and the wing is extended from the seventh surface of the second outer.

Details of the other embodiments are included in the detailed description and drawings.

In the showerhead assembly and the substrate processing apparatus comprising the same according to the present disclosure, since a thread for coupling a bush unit to an insertion groove of a showerhead plate is not formed, cracks do not occur, and subsequent process efficiency may be improved by easy decomposition of the bush unit when cleaning or re-polishing is performed, and a stable trapezoidal structure may be provide to improve a fastening force.

The effects according to the embodiment of the present disclosure are not limited to those mentioned above, and more various effects are included in the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a semiconductor device fabricating facility equipped with a substrate processing apparatus according to some embodiments of the present disclosure;

FIG. 2 is a view illustrating a substrate processing apparatus provided with a showerhead assembly according to some embodiments of the present disclosure;

FIG. 3 is a view illustrating an area A of FIG. 2;

FIG. 4 is a view illustrating a showerhead plate of a showerhead assembly according to the first embodiment of the present disclosure;

FIG. 5 is an exploded perspective view illustrating a bush unit of a showerhead assembly according to the first embodiment of the present disclosure;

FIG. 6 is a perspective view illustrating a bush unit of a showerhead assembly according to the first embodiment of the present disclosure;

FIG. 7 is a perspective view illustrating a bush unit in another direction of FIG. 6;

FIG. 8 is a view illustrating a state in which a first outer of a showerhead assembly according to the first embodiment of the present disclosure is inserted into an inlet of an insertion groove;

FIG. 9 is a view illustrating a process of inserting a first outer of a showerhead assembly according to the first embodiment of the present disclosure into an insertion groove;

FIG. 10 is a view illustrating a state that a first outer of a showerhead assembly according to the first embodiment of the present disclosure is moved to be adjacent to a fourth surface on an inner wall of an insertion groove;

FIG. 11 is a view illustrating a state that a second outer of a showerhead assembly according to the first embodiment of the present disclosure is inserted into an insertion groove;

FIG. 12 is a view illustrating a state that a gas distribution plate is disposed above a showerhead plate of a showerhead assembly according to the first embodiment of the present disclosure;

FIG. 13 is a perspective view illustrating a bush unit of a showerhead assembly according to the second embodiment of the present disclosure;

FIG. 14 is a view illustrating a state that a bush unit of a showerhead assembly according to the third embodiment of the present disclosure is separated from a showerhead plate;

FIG. 15 is a view illustrating a state that a first piece of a showerhead assembly according to the third embodiment of the present disclosure is inserted into a showerhead plate;

FIG. 16 is a view illustrating a state that a second piece of a showerhead assembly according to the third embodiment of the present disclosure is disposed at an inlet of an insertion groove;

FIG. 17 is a view illustrating a state that a second piece of a showerhead assembly according to the third embodiment of the present disclosure is inserted into an insertion groove; and

FIG. 18 is a view illustrating a state that a fastening unit of a showerhead assembly according to the third embodiment of the present disclosure is inserted into an insertion groove.

### DETAILED DESCRIPTION OF THE DISCLOSURE

Hereinafter, the preferred embodiment of the present disclosure will be described in detail with reference to the accompanying drawings. Advantages and features of the present disclosure and methods of achieving the advantages and features will be apparent from the following embodiments that will be described in more detail with reference to the accompanying drawings. It should be noted, however, that the present disclosure is not limited to the following embodiments and may be implemented in various forms. The embodiments are provided only to disclose the present disclosure and let those skilled in the art understand the scope of the present disclosure. In the drawings, the embodiments of the present disclosure are defined by the scope of claims. The same reference numerals denote the same elements throughout the specification.

The terms used herein are for the purpose of embodiments and are not intended to be limit the present disclosure. In the present disclosure, unless referred to the contrary, the singular forms are intended to include the plural forms. The terms “comprises” and/or “comprising” used herein specify the presence of stated elements, steps, operations and/or targets but do not preclude the presence or addition of one or more other elements, steps, operations and/or targets.

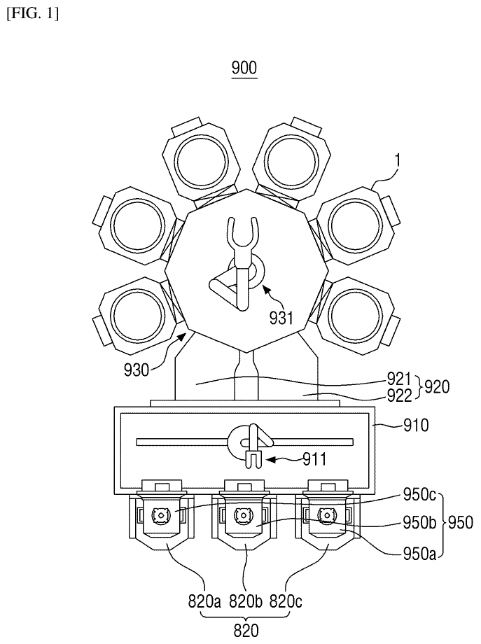

FIG. 1 is a view illustrating a semiconductor device fabricating facility equipped with a substrate processing apparatus according to some embodiments of the present disclosure.

Referring to FIG. 1, a semiconductor device fabricating facility 900 may include a load port module 820, an index module 910, a load-lock chamber 920, a transfer chamber 930 and a process chamber. Hereinafter, the process chamber will be referred to as a substrate processing apparatus 1.

The semiconductor device fabricating facility 900 is a system that processes a plurality of substrates W (for example, a wafer) through various processes such as an etching process and a cleaning process. The semiconductor device fabricating facility 900 may be implemented as a multi-chamber type substrate processing system that includes transfer robots 911 and 931 responsible for substrate transfer and a plurality of substrate processing apparatuses 1 that are substrate processing modules provided near the transfer robots 911 and 931.

A container 950 (for example, a front opening unified pod (FOUP) on which the plurality of substrates W are mounted is seated on the load port module 820. A plurality of load port modules 820 may be disposed in front of the index module 910.

When the plurality of load port modules 820 are disposed in front of the index module 910, the container 950 seated on the respective load port modules 820 may mount different objects thereon. For example, when three load port modules 820 are disposed in front of the index module 910, a first container 950a seated on a first load port 820a of a left side may mount a wafer-type sensor (not shown) thereon, a second container 950b seated on a second load port 820b of a center side may mount the substrate W thereon, and a third container 950c seated on a third load port 820c of a right side may mount a consumable component (not shown) thereon, but the present embodiment is not limited thereto. The containers 950a, 950b and 950c respectively seated on the load ports 820a, 820b and 820c may be modified as necessary, and for example, the same object may be mounted thereon.

The index module 910 is disposed between the load port module 820 and the load lock chamber 920 to perform interface to transfer the substrate W between the container 950 on the load port module 820 and the load lock chamber 920. The index module 910 may be implemented as a front end module (FEM), but is not limited thereto.

The index module 910 may include a first transfer robot 911 responsible for transfer of the substrate W. The first transfer robot 911 may operate in an atmospheric pressure environment, and may transfer the substrate W between the container 950 and the load lock chamber 920.

The load lock chamber 920 may serve as a buffer between an input port and an output port on the semiconductor device fabricating facility 900. The load lock chamber 920 may have a buffer stage therein, in which the substrate W temporarily waits.

A plurality of load lock chambers 920 may be provided between the index module 910 and the transfer chamber 930. In the present embodiment, for example, two load lock chambers 921 and 922 such as the first load lock chamber 921 and the second load lock chamber 922 may be provided between the index module 910 and the transfer chamber 930.

The first load lock chamber 921 and the second load lock chamber 922 may be disposed in a horizontal direction between the index module 910 and the transfer chamber 930. For example, the first load lock chamber 921 and the second load lock chamber 922 may be provided in a mutually symmetrical single layer structure that is disposed side by side in a left-right direction. Alternatively, the first load lock chamber 921 and the second load lock chamber 922 may be disposed in a vertical direction between the index module 910 and the transfer chamber 930.

The first load lock chamber 921 may transfer the substrate W from the index module 910 to the transfer chamber 930, and the second load lock chamber 922 may transfer the substrate W from the transfer chamber 930 to the index module 910, but the present embodiment is not limited thereto. The first load lock chamber 921 may transfer the substrate W from the transfer chamber 930 to the index module 910, and the second load lock chamber 922 may transfer the substrate from the index module 910 to the transfer chamber 930.

In the load lock chamber 920, the substrate W may be loaded or unloaded by the second transfer robot 931 of the transfer chamber 930. In the load lock chamber 920, the substrate W may be loaded or unloaded by the first transfer robot 911 of the index module 910.

The load lock chamber 920 may maintain pressure while changing the inside thereof into a vacuum environment and an atmospheric pressure environment by using a gate valve or the like. Therefore, the load lock chamber 920 may prevent a change in an internal air pressure state of the transfer chamber 930.

In detail, when the substrate W is loaded or unloaded by the second transfer robot 931, the load lock chamber 920 may form the inside thereof in the same (or close) vacuum environment as that of the transfer chamber 930. Also, when the substrate W is loaded or unloaded by the first transfer robot 911 (i.e., when a non-processed substrate W is supplied from the first transfer robot 911 or a pre-processed substrate W is transferred to the index module 910), the inside of the load lock chamber 920 may be formed in an atmospheric pressure environment.

The transfer chamber 930 transfers the substrate W between the load lock chamber 920 and the substrate processing apparatus 1. To this end, the transfer chamber 930 may include at least one second transfer robot 931.

The second transfer robot 931 transfers the non-processed substrate W from the load lock chamber 920 to the substrate processing apparatus 1 or transfers the pre-processed substrate W from the substrate processing apparatus 1 to the load lock chamber 920. To this end, each side of the transfer chamber 930 may be connected to the load lock chamber 920 and the plurality of substrate processing apparatuses 1.

Meanwhile, the second transfer robot 931 may operate in a vacuum environment, and may be freely rotated.

The substrate processing apparatus 1 may process the substrate W. The substrate processing apparatus 1 may be implemented as an etching chamber for processing the substrate W by using an etching process, and for example, may be implemented as a plasma reaction chamber for etching the substrate W by using a plasma process.

The substrate processing apparatus 1 may be disposed as a plurality of substrate processing apparatuses 1 around the transfer chamber 930. In this case, each of the substrate processing apparatuses 1 may receive the substrate W from the transfer chamber 930 to process the substrate W, and may provide the processed substrate W to the transfer chamber 930.

The substrate processing apparatus 1 may be formed in a cylindrical shape. The substrate processing apparatus 1 may be made of an alumite on which an anodized film is formed, and the inside thereof may be hermetically configured. Meanwhile, the substrate processing apparatus 1 may be formed in a shape other than a cylindrical shape in the present embodiment.

Hereinafter, the substrate processing apparatus 1 will be described in detail with reference to the drawings.

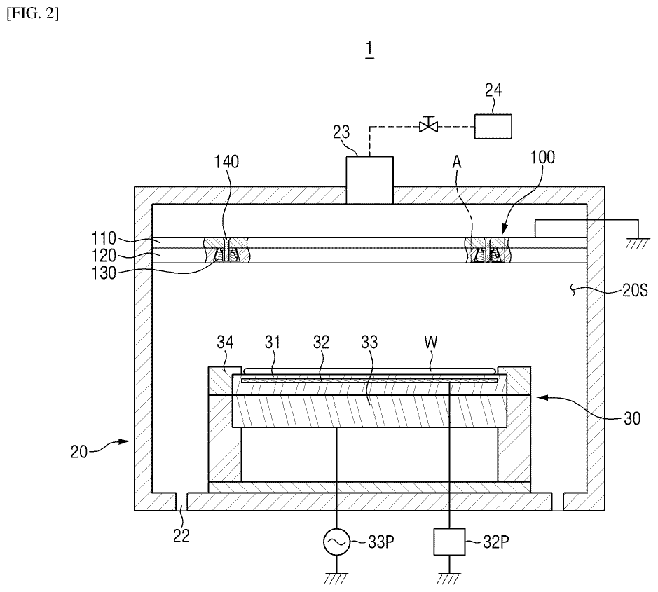

FIG. 2 is a view illustrating a substrate processing apparatus provided with a showerhead assembly according to some embodiments of the present disclosure.

Referring to FIG. 2, the substrate processing apparatus 1 may include a chamber 20, a substrate support unit 30 and a showerhead assembly 100.

In the chamber 20, a substrate processing space 20S may be formed. The substrate processing space 20S may be an etching processing space for etching the substrate W with plasma.

The chamber 20 may be made of a metal material such as aluminum. That is, the chamber 20 may be made of a conductive material, and may be grounded. An opening (not shown) through which the substrate W enters and exits may be formed on a sidewall of the chamber 20, and a door (not shown) may be provided in the opening.

An exhaust hole 22 may be formed on a bottom surface of the chamber 20, a vacuum pump (not shown) may be connected to the exhaust hole 22 so that reaction by-products may be discharged to the outside through the exhaust hole 22, and the substrate processing space 20S may be decompressed at a predetermined pressure during the exhaust process. The substrate processing space 20S may be maintained in a vacuum atmosphere when the substrate W is processed.

A supply hole 23 for inflow of a process gas from the gas supply unit 24 may be formed in an upper portion of the chamber 20. In this case, the process gas may be a gas for processing the substrate W with plasma. The process gas supplied by the gas supply unit 24 may be excited in a plasma state by a plasma source, and may be, for example, a gas containing fluorine.

A liner (not shown) may be provided on an inner circumferential surface of the chamber 20 and/or an outer circumferential surface of the substrate support unit 30. The liner may prevent an inner wall of the chamber 20 and an outer circumferential wall of the substrate support unit 30 from being contaminated during the substrate processing process. That is, the liner may prevent the reaction by-products generated during the process from being deposited on the inner wall of the chamber 20 and the substrate support unit 30.

The substrate support unit 30 may support the substrate W in the substrate processing space 20S. The substrate support unit 30 may have a support surface that supports the substrate W. The substrate support unit 30 may support the substrate W and chuck the supported substrate W.

For example, the substrate support unit 30 may be provided as an electrostatic chuck that adsorbs the substrate W by using an electrostatic force. Alternatively, various modifications may be made in the substrate support unit 30 such as chucking the substrate W in a vacuum adsorption mode.

When the substrate support unit 30 is provided as an electrostatic chuck, the substrate support unit 30 may include a dielectric plate 31, an electrode plate 33 and a ring member 34.

The substrate W may be placed on the dielectric plate 31. The dielectric plate 31 may be provided in a disk shape, and the dielectric plate 31 may be provided in a dielectric substance. The dielectric plate 31 may be supplied with an external power source to apply an electrostatic force to the substrate W. The dielectric plate 31 may be provided with an electrostatic electrode 32. The electrostatic electrode 32 may be electrically connected to a first power source 32P. The first power source 32P may include a direct current power source. A switch (not shown) may be installed between the electrostatic electrode 32 and the first power source 32P.

The electrostatic electrode 32 may be electrically connected to the first power source 32P by ON/OFF of a switch. When the switch is turned on, a direct current may be applied to the electrostatic electrode 32. An electrostatic force may act between the electrostatic electrode 32 and the substrate W by the current applied to the electrostatic electrode 32. The substrate W may be adsorbed and/or fixed to the dielectric plate 31 by the electrostatic force.

The electrode plate 33 may be provided below the dielectric plate 31. An upper surface of the electrode plate 33 may be in contact with a lower surface of the dielectric plate 31. The electrode plate 33 may be provided in a disk shape. The electrode plate 33 may be made of a conductive material such as aluminum. The electrode plate 33 may be electrically connected to a second power source 33P. The second power source 33P may be provided as a high frequency power source that generates high frequency power. The high frequency power source may be provided as a high bias power RF power source. The electrode plate 33 may be applied with high frequency power from the second power source 33P, or may be grounded. That is, the electrode plate 33 may function as a lower electrode.

The ring member 34 may be disposed at an edge area of the substrate support unit 30. The ring member 34 may have a ring shape. The ring member 34 may be provided to surround the dielectric plate 31. The ring member 34 may be provided as a focus ring.

Although not shown in the drawing, the substrate support unit 30 may be provided by passing through a lift pin (not shown) so that a height of the substrate W may be changed.

In the present embodiment, a plasma source may be used for the process for processing the substrate W, and the plasma source may excite the process gas into a plasma state in the chamber 20. A capacitively coupled plasma (CCP) may be used as the plasma source.

The capacitively coupled plasma may include an upper electrode and a lower electrode inside the chamber 20. The upper electrode and the lower electrode may be disposed up and down in parallel with each other inside the chamber 20. The high frequency power may be applied to one of the both electrodes, and the other electrode may be grounded. An electromagnetic field is formed in a space between the two electrodes, and the process gas supplied to the substrate processing space 20S, which is a space between the two electrodes, may be excited in a plasma state.

The process of processing the substrate W may be performed using such plasma. In the present embodiment, the upper electrode may be provided to the showerhead assembly 100, and the lower electrode may be provided to the electrode plate 33. For example, the high frequency power may be applied to the upper electrode and the lower electrode may be grounded, or the high frequency power may be applied to the lower electrode and the upper electrode may be grounded. As a result, an electromagnetic field is generated between the upper electrode and the lower electrode, and the electromagnetic field may excite the process gas provided into the chamber 20 in a plasma state.

The showerhead assembly 100 may be provided to the upper electrode while discharging the process gas from an upper portion of the substrate processing space 20S. For example, the showerhead assembly 100 may include a gas distribution plate 110, a showerhead plate 120, a bush unit 130 and a fastening unit 140.

The gas distribution plate 110 may be provided above the showerhead plate 120 at the upper portion of the substrate processing space 20S. The gas distribution plate 110 may be made of a metal material. The gas distribution plate 110 functions as the upper electrode so that the high frequency power source may be applied thereto, or the gas distribution pate 100 may be grounded.

Further, the gas distribution plate 110 may distribute the process gas supplied from the gas supply unit 24 to the substrate processing space 20S. The gas distribution plate 110 may diffuse the process gas supplied from the upper portion. A gas introduction hole (not shown) may be formed in the gas distribution plate 110. The gas introduction hole may be formed at a position corresponding to a gas supply hole. That is, the gas introduction hole may be communicated with the gas supply hole. That is, the process gas supplied from the upper portion of the showerhead assembly 100 may be supplied to a lower portion of the showerhead plate 120 by passing through the gas introduction hole and the gas supply hole sequentially.

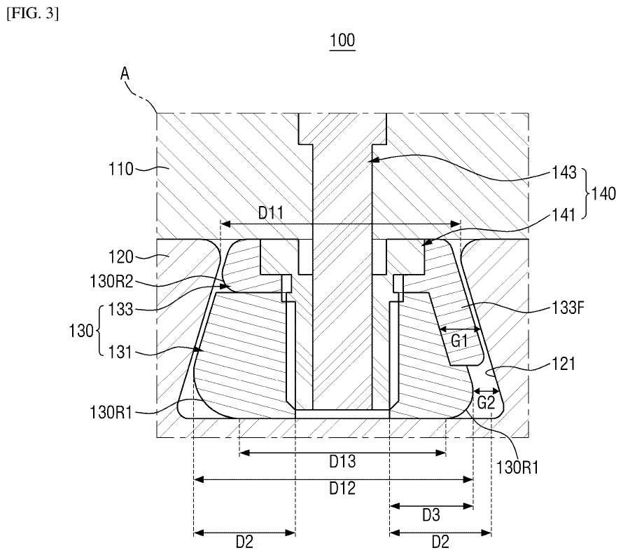

The gas distribution plate 110 may be formed with a first coupling groove 110H (see FIG. 12) to be coupled to the showerhead plate 120. The first coupling groove 110H may have a thread for screwing a bolt 143 (see FIG. 3) on an inner circumferential surface thereof.

The showerhead plate 120 may be provided in a plate shape. A surface of the showerhead plate 120 may be anodized in order to prevent an arc from being generated on a bottom surface by plasma. A cross-section of the showerhead plate 120 may be provided to have the same shape and cross-sectional area as those of the substrate support unit 30. A plurality of gas supply holes (not shown) may be formed in the showerhead plate 120. The gas supply holes may be formed by passing through an upper surface and a lower surface of the showerhead plate 120 in a vertical direction.

The showerhead plate 120 is made of a silicon (Si) material and thus may be made of ceramic. This is to be provided as a material that reacts with plasma generated from the process gas supplied by the gas supply unit 24 to generate a compound. Unlike the gas distribution plate 110 made of a metal material, since the showerhead plate 120 is made of ceramic, there is a risk of damage when the bolt 143 is coupled thereto, and thus the showerhead plate 120 is coupled to the gas distribution plate 110 by using the bush unit 130 as a medium.

That is, the showerhead plate 120 positioned below the gas distribution plate 110 may have an insertion groove 121 formed at a position facing the first coupling groove 110H up and down. The insertion groove 121 may be provided to be coupled to the gas distribution plate 110 by using the bush unit 130 and the fastening unit 140 as media.

Hereinafter, a coupling structure of the showerhead assembly 100 will be described with reference to the drawings.

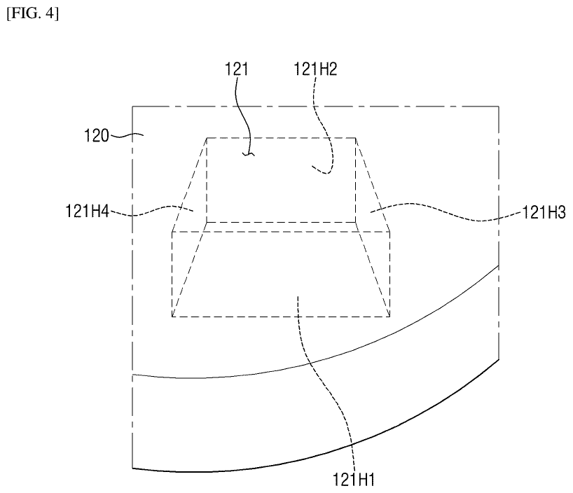

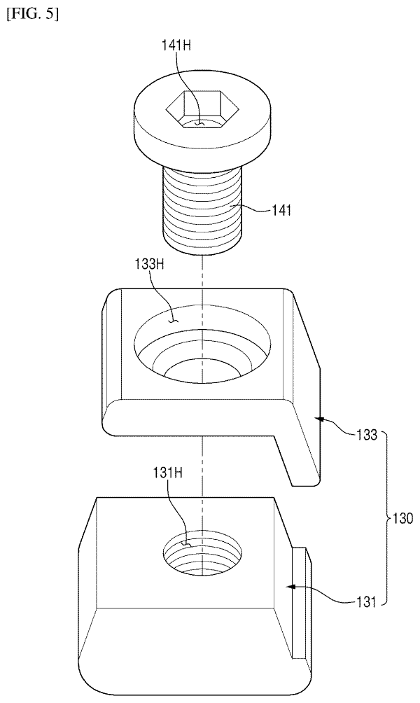

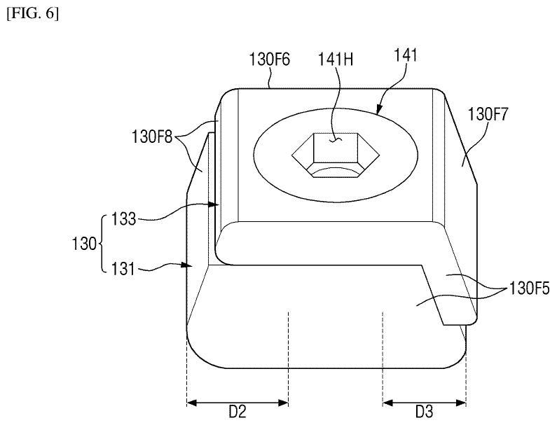

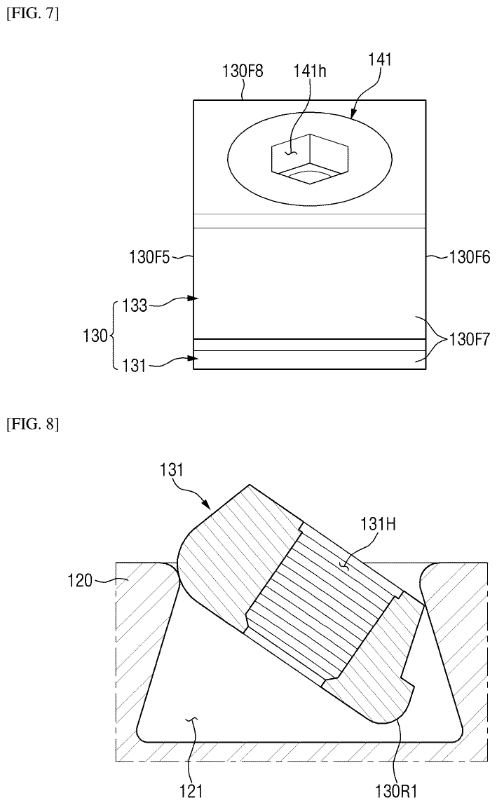

FIG. 3 is a view illustrating an area A of FIG. 2. FIG. 4 is a view illustrating a showerhead plate of a showerhead assembly according to the first embodiment of the present disclosure. FIG. 5 is an exploded perspective view illustrating a bush unit of a showerhead assembly according to the first embodiment of the present disclosure. FIG. 6 is a perspective view illustrating a bush unit of a showerhead assembly according to the first embodiment of the present disclosure. FIG. 7 is a perspective view illustrating a bush unit in another direction of FIG. 6.

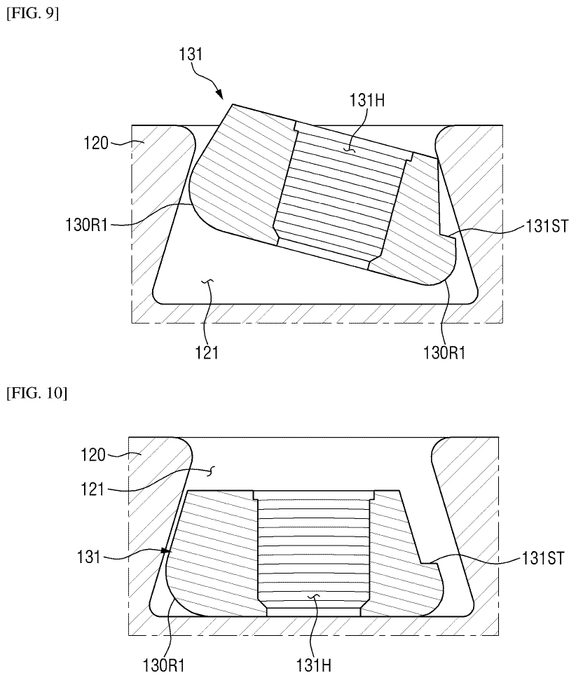

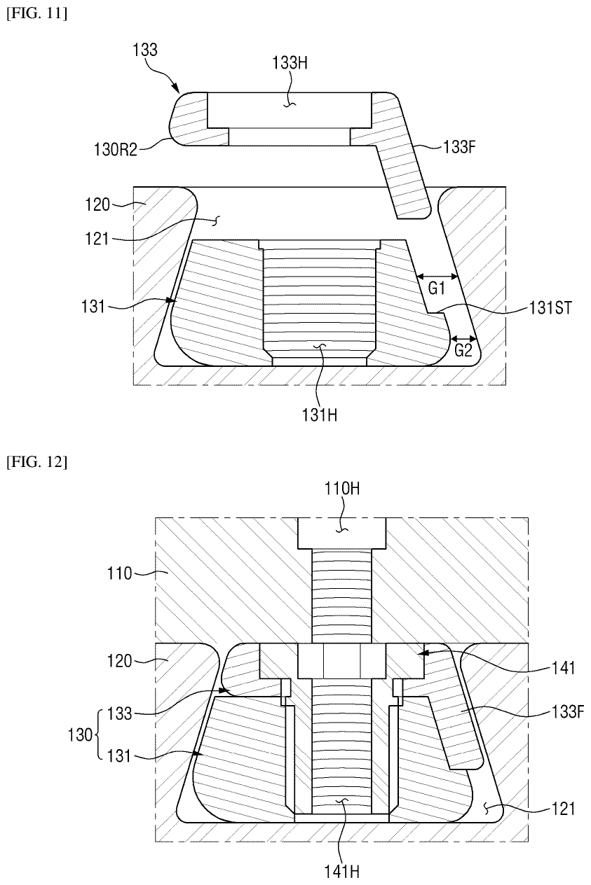

Also, FIGS. 8 to 12 are views illustrating a coupling process of a bush unit, wherein FIG. 8 is a view illustrating a state in which a first outer of a showerhead assembly according to the first embodiment of the present disclosure is inserted into an inlet of an insertion groove, and FIG. 9 is a view illustrating a process of inserting a first outer of a showerhead assembly according to the first embodiment of the present disclosure into an insertion groove. Also, FIG. 10 is a view illustrating a state that a first outer of a showerhead assembly according to the first embodiment of the present disclosure is moved to be adjacent to a fourth surface on an inner wall of an insertion groove, FIG. 11 is a view illustrating a state that a second outer of a showerhead assembly according to the first embodiment of the present disclosure is inserted into an insertion groove, and FIG. 12 is a view illustrating a state that a gas distribution plate is disposed above a showerhead plate of a showerhead assembly according to the first embodiment of the present disclosure.

Referring to FIGS. 3 to 12, the showerhead assembly 100 may include a gas distribution plate 110, a showerhead plate 120, a bush unit 130 and a fastening unit 140.

First, referring to FIG. 12, a first coupling groove 110H may be formed in the gas distribution plate 110. The first coupling groove 110H may be formed with a thread for the showerhead plate 120 to be coupled thereto via the bush unit 130 and the fastening unit 140. That is, the first coupling groove 110H may be formed with a thread on an inner circumferential surface to which the bolt 143 is screwed.

Referring to FIGS. 3, 4 and 8 to 12, the insertion groove 121 of the showerhead plate 120 may be formed as a polyhedral space so that the bush unit 130 does not run idle, even without a separate anti-rotation element. In other words, the bush unit 130 does not form a structure such as a cylinder or cone, but has a structure in which several surfaces are formed and correspondingly, the space of the insertion groove 121 may be formed as a polyhedral space.

For example, referring to FIG. 4, the insertion groove 121 may include a first surface 121H1, a second surface 121H2, a third surface 121H3 and a fourth surface 121H4 in a circumferential direction, and may include a bottom surface (not shown as a reference numeral) because upper and lower portions are not completely penetrated. In this case, the second surface 121H2 may be disposed at a position facing the first surface 121H1. The third surface 121H3 may be connected to each of the first surface 121H1 and the second surface 121H2. The fourth surface 121H4 may face the third surface 121H3, and may be connected to each of the first surface 121H1 and the second surface 121H2. In other words, in the insertion groove 121, the first surface 121H1, the third surface 121H3, the second surface 121H2 and the fourth surface 121H4 may be sequentially disposed in a circumferential direction.

The insertion groove 121 may have a larger area on a lower end than on an upper end which is the inlet, and for example, each of the first surface 121H1 and the second surface 121H2 of the insertion groove 121 may constitute a trapezoidal shape. The third surface 121H3 and the fourth surface 121H4 of the insertion groove 121 have the same vertical width and thus may have a square or rectangular shape. Therefore, the third surface 121H3 and the fourth surface 121H4 may constitute an inclined surface in the insertion groove 121, and the first surface 121H1 and the second surface 121H2 may be formed as surfaces perpendicular to the bottom surface in the insertion groove 121.

In this insertion groove 121, since the bush unit 130 forms an undercut structure in which its upper portion is caught inside the insertion groove 121, the showerhead assembly 100 is not arbitrarily separated from the bush unit 130 in the vertical direction, whereby the thread for screwing the bush unit 130 may be omitted on the inner circumferential surface of the insertion groove 121 to enable bare patterning. Therefore, when the bush unit 130 is coupled to the showerhead plate 120, the problem of cracking the showerhead plate 120 due to a coupling force by screwing may be resolved.

In addition, the inlet, which is the upper end of the insertion groove 121, is processed to be curved (rounded), so that the inlet may be formed in a curved surface, but is not limited thereto (see FIG. 3).

Referring to FIGS. 3 and 5 to 12, the bush unit 130 may be provided as a medium for fastening the showerhead plate 120 and the gas distribution plate 110. The bush unit 130 may be made of a Cerazole material, but various modifications may be made in the bush unit 130, like that the bush unit 130 may be made of metal.

The bush unit 130 may have a polyhedral structure so as not to run idle in the insertion groove 121 of the showerhead plate 120.

For example, the bush unit 130 may include a fifth surface 130F5, a sixth surface 130F6, a seventh surface 130F7 and an eighth surface 130F8. In this case, the fifth surface 130F5 may face or contact the first surface 121H1 by corresponding to the first surface 121H1. The sixth surface 130F6 may face or contact the second surface 121H2 by corresponding to the second surface 121H2. The seventh surface 130F7 may face or contact the third surface 121H3 by corresponding to the third surface 121H3. The eighth surface 130F8 may face or contact the fourth surface 121H4 by corresponding to the fourth surface 121H4. That is, in the bush unit 130, the fifth surface 130F5, the seventh surface 130F7, the sixth surface 130F6 and the eighth surface 130F8 may be sequentially disposed in the circumferential direction.

This bush unit 130 may be simply inserted into and fixed to the insertion groove 121 of the showerhead plate 120 without being screwed thereinto. The bush unit 130 has a larger cross-sectional area at the lower end than the upper end, so that the bush unit 130 interferes with the showerhead plate 120 in the vertical direction, whereby the showerhead plate 120 may be prevented from falling in a downward direction of the bush unit 130 by an undercut structure of the insertion groove 121 of the showerhead plate 120.

To this end, the bush unit 130 may have a larger area on the lower end than on the upper end by corresponding to the shape of the insertion groove 121, and for example, at least one surface of the bush unit 130 may have a trapezoidal shape. Each of the fifth surface 130F5 and the sixth surface 130F6 of the bush unit 130 may constitute a trapezoidal shape. In addition, the seventh surface 130F7 and the eighth surface 130F8 of the bush unit 130 may have the same vertical width and thus may have a square or rectangular shape. Therefore, the seventh surface 130F7 and the eighth surface 130F8 may constitute an inclined surface of the bush unit 130, and the fifth surface 130F5 and the sixth surface 130F6 may constitute a vertical surface of the bush unit 130.

In this case, the trapezoidal, square and rectangular shapes of the bush unit 130 are representative, and may include all modified shapes of trapezoidal, square and rectangular shapes. That is, the shapes such as trapezoidal and rectangular shapes of the bush unit are defined for understanding and convenience, and may include all shapes such as a shape in which a curved surface is formed by omitting a corner of a trapezoid, or a shape in which a portion is cut.

In addition, the bush unit 130 may be formed with second coupling grooves 131H and 133H. The second coupling grooves 131H and 133H, which are grooves to which the fastening unit 140 is coupled, may have the same central axis as that of the first coupling groove 110H and the insertion groove 121. In addition, a thread may be formed on inner circumferential surfaces of the second coupling grooves 131H and 133H so that an inner 141 of the fastening unit 140 is screwed to the second coupling grooves 131H and 133H.

However, the thread may be omitted from the second coupling groove 133H of the second outer 133, and is formed to be larger than that of the second coupling groove 131H of the first outer 131, so that the inner 141 may be screwed only to the second coupling groove 131H of the first outer 131 and the second outer 133 may only pass through the thread. In this way, various modifications may be made in the thread.

In addition, the bush unit 130 may have a structure that is inserted into the insertion groove 121 without interfering with the undercut structure of the insertion groove 121. For example, the bush unit 130 may have one side (left side based on FIG. 3) and the other side (right side based on FIG. 3), which are asymmetrical based on the second coupling grooves 131H and 133H, and may be separated into two or more.

For example, the bush unit 130 may include a first outer 131 and a second outer 133, which are separated from each other in the vertical direction. In this case, the first outer 131 and the second outer 133 are asymmetrical based on the second coupling grooves 131H and 133H, but the first outer 131 may be formed to be biased to one side (left side based on FIG. 3) and the second outer 133 may be formed to be biased to the other side (right side based on FIG. 3). That is, the first outer 131 interferes with one side inside the insertion groove 121 and the second outer 133 interferes with the other side inside the insertion groove 121, so that the first outer 131 may be prevented from being detached by the second outer 133 and the second outer 133 may be prevented from being detached by the first outer 131.

Referring to FIG. 3, the first outer 131 is disposed downward inside the insertion groove 121, and when the second coupling grooves 131H and 133H constitute the same central axis as that of the insertion groove 121, one side (left side based on FIG. 3) may contact or be adjacent to the insertion groove 121, and a first gap G1 may be formed with the insertion groove 121 at the other side. A step difference 131ST is formed in the first outer 131 so that the first gap G1 is formed at an upper portion of the step difference 131ST, and a second gap G2 having the same or smaller distance as or than the first gap G1 may be formed at a lower portion of the step difference 131ST.

That is, a width D2 of one side of the first outer 131 may be greater than a width D3 of the other side based on the second coupling grooves 131H and 133H.

The second outer 133 may be disposed above the first outer 131 inside the insertion groove 121. The second outer 133 has an asymmetric structure similarly to the first outer 131, but unlike the first outer 131, a width/length/size of the other side may be larger than that of one side (left side based on FIG. 3). For example, the second outer 133 may include a wing 133F extended to be inserted into the first gap G1, and the wing 133F may be provided on the other side (right side based on FIG. 3) of the second outer 133.

The wing 133F may be extended to be longer than the edge of the upper end of the insertion groove 121 in a projection from the top to the bottom so as to interfere with the showerhead plate 120 in the vertical direction. That is, referring to FIG. 3, the wing 133F may be extended further to the right than the edge of the insertion groove 121.

Hereinafter, the asymmetric structure of the first outer 131 and the second outer 133 will be described.

In the first outer 131, each of the fifth surface 130F5 and the sixth surface 130F6 may have one side (left side based on FIGS. 3 and 6) and the other side (right side based on FIGS. 3 and 6), which are formed asymmetrically based on the second coupling grooves 131H and 133H. Referring to FIG. 7, a width between the fifth surface 130F5 and the sixth surface 130F6 may be the same from the upper end to the lower end.

Referring back to FIGS. 3 and 6, instead of a corner, a first curved surface 130R 1 may be formed between the seventh surface 130F7 of the first outer 131 and the bottom surface (not shown as a reference numeral) of the first outer 131 and between the eighth surface 130F8 of the first outer 131 and the bottom surface of the first outer 131. The first curved surface 130R1 may be inserted into the insertion groove 121 without interference as shown in FIG. 8 because the corner of the first outer 131 may be formed by curved processing.

A maximum width D12 of the first outer 131 between the seventh surface 130F7 of the first outer 131 and the eighth surface 130F8 of the first outer 131, that is, the maximum width D12 of each of the fifth surface 130F5 and the sixth surface 130F6 may be greater than a width D11 of the inlet which is the upper end of the insertion groove 121. A width D13 of the bottom surface of the first outer 131 may be smaller than the width D11 of the inlet which is the upper end of the insertion groove 121. This is to prevent the first outer 131 from being easily separated from the insertion groove 121 even while the first outer 131 is inserted into the insertion groove 121 by the first curved surface 130R1.

The second outer 133 may be formed with a second curved surface 130R2 without forming a corner between the eighth surface 130F8 of the second outer 133 and the bottom surface of the second outer 133 so that the second outer 133 may be easily inserted into the insertion groove 121 as shown in FIG. 11. In addition, the wing 133F of the second outer 133 may be extended from the seventh surface 130F7 of the second outer 133.

The fastening unit 140 may be coupled to the first coupling groove 110H and the second coupling grooves 131H and 133H to fasten the showerhead plate 120, into which the bush unit 130 is fitted, and the gas distribution plate 110.

For example, the fastening unit 140 may be coupled to the second coupling grooves 131H and 133H. The fastening unit 140 may include an inner 141 and a bolt 143.

The inner 141 may be formed with a third coupling groove 141H having the same central axis as that of the second coupling grooves 131H and 133H, and may be made of a metal or plastic material. A thread of the third coupling groove 141H may be formed subsequently to the thread of the first coupling groove 110H so that the bolt 143 is coupled to the third coupling groove 141H and the first coupling groove 110H. That is, a diameter of the third coupling groove 141H may be the same as a diameter of the first coupling groove 110H.

The bolt 143 may be coupled to the third coupling groove 141H and the first coupling groove 110H to fasten the showerhead plate 120 and the gas distribution plate 110. In this case, a thread may be formed on an outer circumferential surface of the inner 141 so that the inner 141 is screwed to the second coupling grooves 131H and 133H.

Hereinafter, a process in which the bush unit 130 is inserted into the insertion groove 121 of the showerhead plate 120 will be described.

First, referring to FIGS. 8 and 9, since the first outer 131 may be first inserted into the insertion groove 121. However, since the maximum width D12 of the first outer 131, that is, the maximum width D12 of each of the fifth surface 130F5 and the sixth surface 130F6 is greater than the width D11 of the inlet which is the upper end of the insertion groove 121, the first outer 131 may be tilted and inserted into the insertion groove 121. At this time, the width D13 of the bottom surface of the first outer 131 is smaller than the width D11 of the inlet which is the upper end of the insertion groove 121 and the first curved surface 130R1 is formed so that the first outer 131 may be easily inserted into the insertion groove 121.

Subsequently, referring to FIG. 10, the first outer 131 may be pushed so as to be in contact with or close to the fourth surface 121H4 which is the left side of the insertion groove 121. This is to easily insert the second outer 133 into the insertion groove 121.

Referring to FIG. 11, the second outer 133 is inserted into the insertion groove 121 so that the wing 133F of the second outer 133 is inserted into the first gap G1 between the first outer 131 and the third surface 121H3 of the insertion groove 121.

Then, referring to FIG. 12, the inner 141 of the fastening unit 140 may be inserted into the second coupling grooves 131H and 133H. In this way, after the bush unit 130 and the inner 141 are inserted into the insertion groove 121, the gas distribution plate 110 may be disposed above the showerhead plate 120. In this case, the gas distribution plate 110 may be disposed so that the central axes of the second coupling grooves 131H and 133H and the first coupling groove 110H are the same as each other.

The bush unit 130 of the first embodiment includes a first outer 131 and a second outer 133, which are separated from each other in the vertical direction, but is not limited thereto, and the bush unit 130 may have a structure separated in a left-right circumferential direction.

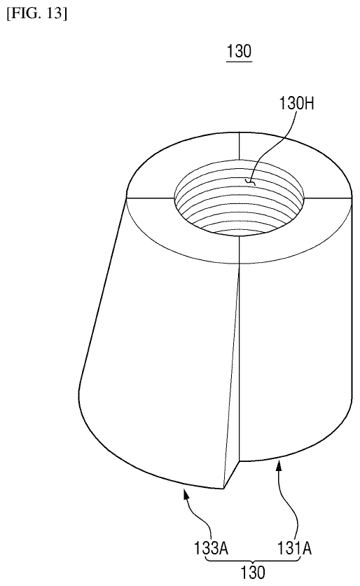

Hereinafter, a modified example of the present embodiment will be described with reference to FIGS. 13 to 18, and a redundant description of the same elements performing the same function will be omitted.

FIG. 13 is a perspective view illustrating a bush unit of a showerhead assembly according to the second embodiment of the present disclosure. The following description will be based on differences from the description made with reference to FIGS. 3 to 12, with reference to FIG. 13.

Referring to FIG. 13, the bush unit 130 may include a first piece 131A and a second piece 133A, which are separated from each other in the circumferential direction. Since the fastening unit 140 includes an inner 141 and a bolt 143 in the same manner as or similarly to the first embodiment, a redundant description will be omitted.

In addition, the insertion groove 121 of the second embodiment may correspond to a shape of the bush unit 130 of the second embodiment. That is, an area of the insertion groove 121 into which the first piece 131A is inserted may correspond to a cylindrical shape, and an area of the insertion groove 121 into which the second piece 133A is inserted may have a shape corresponding to a shape of a pyramid/conc.

The first piece 131A may have the same width from the upper end to the lower end so that it may be formed in a straight line without an inclined surface. That is, the first piece 131A may have a structure that is simply inserted into the insertion groove 121 in the vertical direction.

The second piece 133A may have a cross-sectional area of a lower end, which is larger than that of an upper end so that the bush unit 130 is not detached from the insertion groove 121. For example, the second piece 133A may have a width that is increased from the upper end to the lower end, so that an inclined surface may be formed.

Each of the first piece 131A and the second piece 133A may be provided as one or more. For example, the bush unit 130 may be separated into four to include three first pieces 131A and one second piece 133A. Alternatively, two first pieces 131A of the bush unit 130 separated into four and two second pieces 133A may be provided, and various modifications in which the insertion groove 121 is formed to correspond to the formation of the bush unit 130 are possible.

In the bush unit 130, the second piece 133A having a large lower end may be first inserted into the insertion groove 121 and then the first piece 131A may be easily inserted thereinto. The bush unit 130 has a structure separated in the left-right circumferential direction, but the fastening unit 140 may be coupled and fixed inside the insertion groove 121.

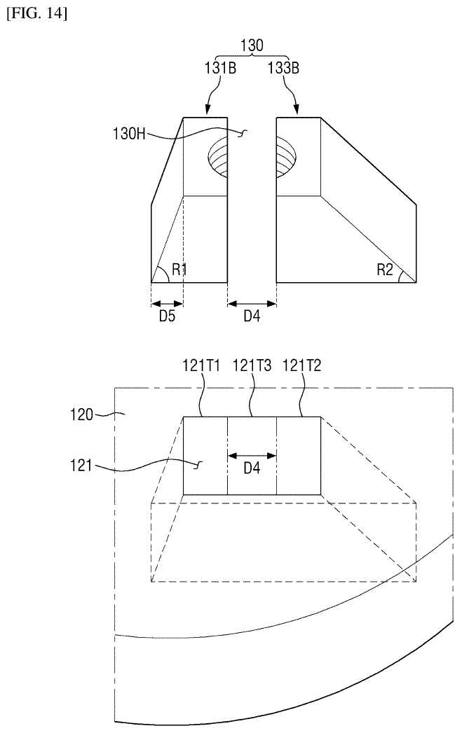

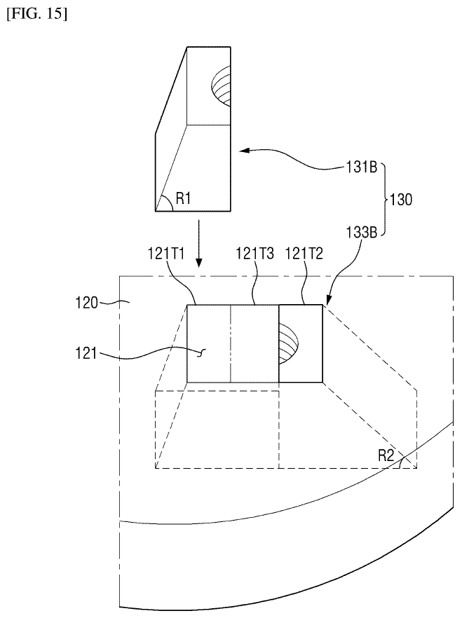

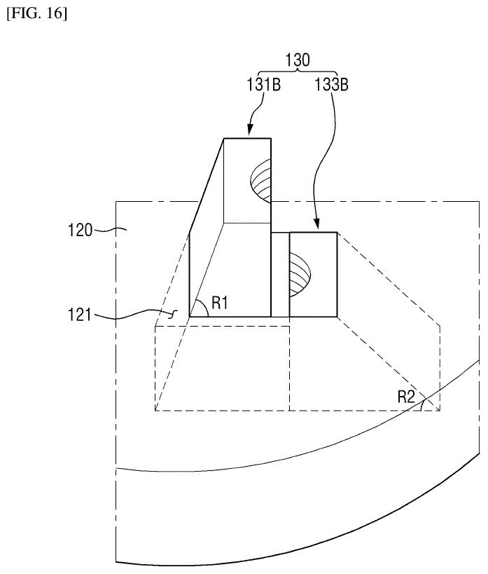

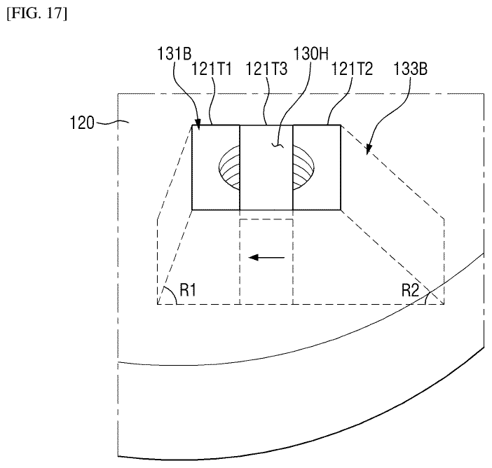

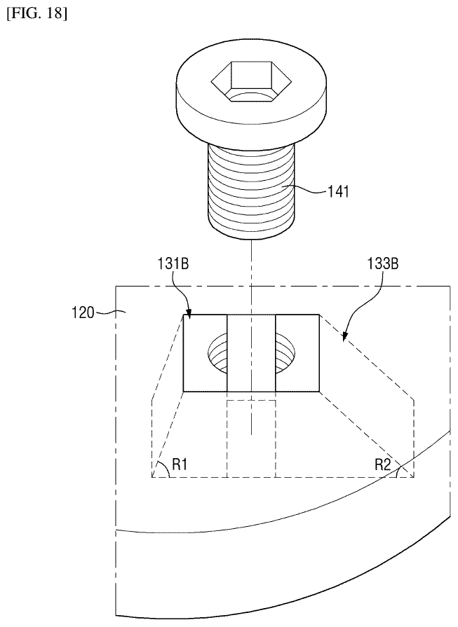

FIG. 14 is a view illustrating a state that a bush unit of a showerhead assembly according to the third embodiment of the present disclosure is separated from a showerhead plate, FIG. 15 is a view illustrating a state that a first piece of a showerhead assembly according to the third embodiment of the present disclosure is inserted into a showerhead plate, FIG. 16 is a view illustrating a state that a second piece of a showerhead assembly according to the third embodiment of the present disclosure is disposed at an inlet of an insertion groove, FIG. 17 is a view illustrating a state that a second piece of a showerhead assembly according to the third embodiment of the present disclosure is inserted into an insertion groove, and FIG. 18 is a view illustrating a state that a fastening unit of a showerhead assembly according to the third embodiment of the present disclosure is inserted into an insertion groove. The following description will be based on differences from the description made with reference to FIGS. 3 to 13, with reference to FIGS. 14 to 18.

Since the fastening unit 140 of the third embodiment includes an inner 141 and a bolt 143 in the same manner as or similarly to the first embodiment and the second embodiment, a redundant description will be omitted.

Referring to FIGS. 14 to 18, the bush unit 130 of the third embodiment may include a first piece 131B and a second piece 133B, which are separated in the circumferential direction similarly to the second embodiment. And, similarly to the bush unit 130 of the first embodiment, the bush unit 130 of the third embodiment may have a polyhedral structure in which two surfaces have a trapezoidal shape and the remaining two surfaces have a square/rectangular shape. Correspondingly, the insertion groove 121 of the third embodiment may have a polyhedral space including a trapezoidal shape, and may have an area of the lower end, which is larger than that of the upper end.

Similarly to the first and second embodiments, the bush unit 130 of the third embodiment may be inserted into the insertion groove 121, and may be formed with a second coupling groove 130H having the same central axis as that of the first coupling groove 110H.

However, the second coupling groove 130H of the bush unit 130 according to the third embodiment may be formed in a space between the first piece 131B and the second piece 133B, and a thread to which the inner 141 is coupled may be formed on a surface where the first piece 131B and the second piece 133B face each other. For example, one side (left side based on FIG. 14) of the second coupling groove 130H may be formed in the first piece 131B, and the other side (right side based on FIG. 14) of the second coupling groove 130H may be formed in the second piece 133B. That is, the bush unit 130 according to the third embodiment may be formed in a structure in which a gap is formed between the first piece 131B and the second piece 133B so that the second coupling groove 130H surrounds only a portion of the inner 141 without fully surrounding the inner 141.

The insertion groove 121 of the third embodiment may include a first area 121T1 including one side (left side based on FIG. 14), a second area 121T2 including the other side (right side based on FIG. 14), and a third area 121T3. In this case, the third area 121T3 is an area between the first area 121T1 and the second area 121T2.

The first piece 131B and the second piece 133B, which are separated from each other in the circumferential direction, are not provided in the third area 121T3. For example, the first piece 131B may be positioned in the first area 121T1, and the second piece 133B may be positioned in the second area 121T2.

An inclined angle R1 of the first piece 131B may be equal to or greater than an inclined angle R2 of the second piece 133B. For example, the inclined angle R1 of the first piece 131B is formed to be greater than the inclined angle R2 of the second piece 133B, so that the first piece 131B and the second piece 133B may be asymmetrical. The second piece 133B, which is inserted to be earlier than the first piece 131B, may have a cross-sectional area of the lower end, which is larger than that of the first piece 131B.

In addition, as shown in FIGS. 16 and 17, the lower end area of the first piece 131B may be equal to or smaller than an area of a sum of the first area 121T1 and the third area 121T3 so that the first piece 131B may be inserted into the insertion groove 121.

The bush unit 130 of the first to third embodiments as described above includes the first outer 131 and the second outer 133, which are separated from each other in the vertical direction or includes first pieces 131A and 131B and second pieces 133A and 133B, which are separated from each other in the left-right circumferential direction, but is not limited thereto, and another modification example may be made in the bush unit 130 by combination of the first to third embodiments. That is, various modification examples may be made in the bush unit 130, like that at least one of the first outer 131 or the second outer 133 of the bush unit 130 is separated in the left-right circumferential direction so that the first outer 131 may be provided as the first pieces 131A and 131B and the second pieces 133A and 133B.

Although the embodiments of the present disclosure have been described with reference to the accompanying drawings, it will be apparent to those skilled in the art that the present disclosure may be embodied in other specific forms without departing from the technical spirits and essential characteristics of the present disclosure. Thus, the above-described embodiments are to be considered in all respects as illustrative and not restrictive.

What is claimed is:

1. A showerhead assembly of a substrate processing apparatus, the showerhead assembly comprising:
a gas distribution plate in which a first coupling groove is formed;
a showerhead plate provided below the gas distribution plate and provided with an insertion groove formed at a position facing the first coupling groove in a vertical direction;
a bush unit inserted into the insertion groove and formed with a second coupling groove having the same central axis as that of the first coupling groove; and
a fastening unit coupled to the first coupling groove and the second coupling groove,
wherein the insertion groove has an area of a lower end, which is larger than that of an upper end, and
the bush unit has one side and the other side, which are asymmetrical based on the second coupling groove, and is separated into two or more.

2. The showerhead assembly of claim 1, wherein the bush unit includes a first outer and a second outer, which are separated from each other in the vertical direction,
the first outer is disposed at a lower portion inside the insertion groove, has one side that is in contact with the insertion groove and the other side formed with a first gap with the insertion groove, and
the second outer is disposed above the first outer inside the insertion groove and provided with a wing extended to be inserted into the first gap.

3. The showerhead assembly of claim 2, wherein the wing is extended to be longer than an edge of the upper end of the insertion groove in a projection from the top to the bottom so as to interfere with the showerhead plate in the vertical direction.

4. The showerhead assembly of claim 2, wherein the second coupling groove constitutes the same central axis as that of the insertion groove in the first outer, and
one side of the first outer is wider than the other side based on the second coupling groove.

5. The showerhead assembly of claim 2, wherein the insertion groove includes a first surface, a second surface facing the first surface, a third surface connected to each of the first and second surfaces, and a fourth surface connected to each of the first and second surfaces,
the bush unit includes a fifth surface corresponding to the first surface, a sixth surface corresponding to the second surface, a seventh surface corresponding to the third surface, and an eighth surface corresponding to the fourth surface, and
each of the first surface, the second surface, the fifth surface and the sixth surface has a trapezoidal shape.

6. The showerhead assembly of claim 5, wherein a width between the fifth surface and the sixth surface is the same from an upper end to a lower end.

7. The showerhead assembly of claim 2, wherein the first outer is formed with a step difference, the first gap is formed above the step difference, and a second gap having a distance the same as or smaller than that of the first gap is formed below the step difference.

8. The showerhead assembly of claim 2, wherein a lower end of each of one side and the other side of the first outer is formed with a first curved surface without a corner,
a maximum width of the first outer is greater than a width of the upper end of the insertion groove, and
a width of a bottom surface of the first outer is smaller than the width of the upper end of the insertion groove.

9. The showerhead assembly of claim 8, wherein the second outer is formed with a second curved surface without a corner at a lower end of one side, and is formed with a wing at the other side.

10. The showerhead assembly of claim 1, wherein the bush unit includes a first piece and a second piece, which are separated from each other in a circumferential direction,
the first piece has the same width from an upper end to a lower end so that it is formed in a straight line without an inclined surface, and
the second piece has a width that is increased from an upper end to a lower end, so that an inclined surface is formed.

11. The showerhead assembly of claim 1, wherein the fastening unit includes
an inner coupled to the second coupling groove and formed with a third coupling groove while having the same central axis as that of the second coupling groove, and
a bolt coupled to the third coupling groove and the first coupling groove.

12. The showerhead assembly of claim 11, wherein the showerhead plate is made of a silicon material,
the bush unit is made of a Cerazole material, and
the inner is made of a metal or plastic material.

13. A showerhead assembly of a substrate processing apparatus, the showerhead assembly comprising:
a gas distribution plate in which a first coupling groove is formed;
a showerhead plate provided below the gas distribution plate and formed with an insertion groove at a position facing the first coupling groove in a vertical direction;
a bush unit inserted into the insertion groove and formed with a second coupling groove having the same central axis as that of the first coupling groove; and
a fastening unit coupled to the first coupling groove and the second coupling groove,
wherein the insertion groove has a larger area on a lower end than on an upper end, and includes a first area having one side, a second area including the other side and a third area between the first area and the second area,
the bush unit includes a first piece and a second piece, which are separated from each other in a circumferential direction and is not provided in the third area,
the first piece is positioned in the first area, the second piece is positioned in the second area, and
the first piece and the second piece are asymmetrical.

14. The showerhead assembly of claim 13, wherein the second coupling groove is formed in a space between the first piece and the second piece, and
a thread to which the fastening unit is screw-coupled is formed on a surface where the first piece and the second piece face each other.

15. The showerhead assembly of claim 13, wherein an inclined angle of the first piece is equal to or greater than an inclined angle of the second piece.

16. The showerhead assembly of claim 15, wherein an area of a lower end of the first piece is the same as or smaller than an area of a sum of the first area and the third area.

17. The showerhead assembly of claim 13, wherein the fastening unit includes
an inner coupled to the second coupling groove and formed with a third coupling groove having the same central axis as that of the second coupling groove, and
a bolt coupled to the third coupling groove and the first coupling groove.

18. The showerhead assembly of claim 17, wherein the showerhead plate is made of a silicon material,
the bush unit is made of a Cerazole material, and
the inner is made of a metal or plastic material.

19. The showerhead assembly of claim 13, wherein the insertion groove includes a first surface, a second surface facing the first surface, a third surface connected to each of the first surface and the second surface, and a fourth surface connected to each of the first surface and the second surface,
the bush unit includes a fifth surface corresponding to the first surface, a sixth surface corresponding to the second surface, a seventh surface corresponding to the third surface and an eighth surface corresponding to the fourth surface, and
each of the first surface, the second surface, the fifth surface and the sixth surface has a trapezoidal shape.

20. A substrate processing apparatus comprising:
a chamber in which a substrate processing space for which a plasma etching process is performed is formed;
a substrate support unit supporting a substrate in the substrate processing space;
a gas supply unit supplying a process gas; and
a showerhead assembly provided above the substrate processing space,
wherein the showerhead assembly includes
a gas distribution plate formed with a first coupling groove, distributing the process gas supplied from the gas supply unit to the substrate processing space;
a showerhead plate positioned below the gas distribution plate, formed with an insertion groove at a position facing the first coupling groove in a vertical direction and made of a silicon material;
a bush unit inserted into the insertion groove, formed with a second coupling groove having the same central axis as that of the first coupling groove and insertion groove and made of a Cerazole material; and
a fastening unit coupled to the first coupling groove and the second coupling groove,
the fastening unit includes an inner coupled to the second coupling groove, formed with a third coupling groove having the same central axis as that of the second coupling groove and made of a metal or plastic material, and a bolt coupled to the third coupling groove and the first coupling groove,
the bush unit includes a first outer disposed at a lower portion inside the insertion groove, has one side that is in contact with the insertion groove and the other side formed with a first gap with the insertion groove when the second coupling groove constitutes the same central axis as that of the insertion groove, and
a second outer disposed above the first outer inside the insertion groove and provided with a wing extended to be inserted into the first gap,
the insertion groove has a larger area on a lower end than on an upper end, includes a first surface, a second surface facing the first surface, a third surface connected to each of the first surface and the second surface, and a fourth surface connected to each of the first surface and the second surface,
the bush unit includes a fifth surface corresponding to the first surface, a sixth surface corresponding to the second surface, a seventh surface corresponding to the third surface and an eighth surface corresponding to the fourth surface,
each of the first surface, the second surface, the fifth surface and the sixth surface has a trapezoidal shape,
the fifth surface and the sixth surface of the first outer are formed to be asymmetrical, and a width between the fifth surface and the sixth surface is the same from an upper end to a lower end,
a first curved surface not a corner is formed between the seventh surface of the first outer and a bottom surface of the first outer and between the eighth surface of the first outer and the bottom surface of the first outer,
a maximum width of each of the fifth surface of the first outer and the sixth surface of the first outer is greater than a width of the upper end of the insertion groove,
a width of the bottom surface of the first outer is smaller than the width of the upper end of the insertion groove, and
a second curved surface not a corner is formed between the eighth surface of the second outer and a bottom surface of the second outer, and the wing is extended from the seventh surface of the second outer.
